(19) United States
(12) Patent Application Publication
(10) Pub. No.: US 2008/0075307 A1
(43) Pub. Date: Mar. 27, 2008

(54) Digital Signal Processing Amplifier

(75) Inventor: David E. Ellison, University Place, WA (US)

Correspondence Address: HODGSON RUSS LLP;THE GUARANTY BUILDING, 140 PEARL STREET, SUITE 100, BUFFALO, NY, 14202-4040, US

(73) Assignee: Penton Audio USA, Pawtucket, RI (US)

(21) Appl. No.: 11/668,934

(22) Filed: Jan. 30, 2007

Related U.S. Application Data
(60) Provisional application No. 60/763,317, filed on Jan. 30, 2006.

(51) Int. Cl. H03F 21/00

(52) U.S. Cl. 381/120

(57) ABSTRACT

A digital signal processing amplifier device has a programmable “drag and drop” digital signal processor (DSP), a power supply connected to the DSP and a modular or integral audio amplifier, all housed in a chassis. The amplifier is able to amplify and transmit a signal from the programmable DSP to an output device. To create an audio design, a user, via means of a computer which is in communication with the programmable DSP, may select and assign audio elements to create a virtual audio design. The computer and related software create a set of instructions from the virtual audio design and the instructions are transmitted from the computer to the programmable DSP. The DSP executes the instructions to modify an input signal to provide an output signal, and the output signal is then transmitted by the amplifier to an output device.

### CROSS-REFERENCE TO RELATED APPLICATIONS

This application claims the benefit of U.S. provisional patent application Ser. No. 60/763,317 titled “Digital Signal Processing Amplifier” filed on Jan. 30, 2006, which is incorporated herein by reference.

### FIELD OF THE INVENTION

The invention relates generally to digital signal processing and amplification. More specifically, the invention relates to digital signal processing for modifying an input signal to achieve a desired output signal.

### BACKGROUND OF THE INVENTION

A digital signal processor (DSP) is a specialized microprocessor with an architecture designed specifically for real time processing of a digital signal. A DSP is a programmable device with its own native instruction code. Existing DSPs are capable of carrying out millions of operations per second. As such, DSPs are well suited to modify an audio or video input signal as it is sampled and then output a processed signal, for example to a loudspeaker or video display. DSP technology is nowadays commonplace in such devices as mobile phones, multimedia computers, video recorders, CD players, hard disc drive controllers and modems.

“Drag and Drop” technology is known in the art. Generally, Drag and Drop is the action of clicking on a virtual object displayed on a monitor and dragging it to a different location on the monitor, or onto another virtual object displayed on the monitor.

Currently, manufacturers of audio processors must take multiple components and configure them (wire them together) to form a usable audio device. Alternatively, the manufacturers must rely on an end user to connect audio devices such as amplifiers to the audio processor. However, it generally takes a skilled technician to properly install the desired audio processor into an audio system having the desired inputs and outputs. Manufacturers may therefore encounter increased costs for warehousing multiple types of a component and for employment of skilled technicians.

To eliminate these problems, it is desirable to have a packaged unit that includes both amplifiers and at least one DSP, which may be programmed to suit a user's needs and which can be easily installed by the user at his/her location. Towards these ends, it is desirable to have a programmable digital signal processor, housed within a chassis to allow an end user to precisely modify an input signal.

The programmable digital signal processor allows a designer to modify the operations executed by the DSP. For example, a computer may be used to create audio signal processing designs by dragging audio components from an audio device menu into a design screen. The resulting design may be translated into a set of instructions for the DSP. Once the instructions are loaded to the DSP, the DSP can operate according to the design.

### SUMMARY OF THE INVENTION

A Digital Signal Processing Amplifier (DSPA) device is disclosed. The DSPA may include a DSP and one or more amplifiers. The amplifiers may be modular (i.e. removable) or integral audio power amplifiers, which are capable of driving one or more external loudspeakers, or other output devices. These components may be integrated into a single chassis.

A digital signal processing amplifier according to the invention may include a programmable digital signal processor, a power supply connected to the programmable digital signal processor and an amplifier, all housed in a chassis. The programmable digital signal processor is in communication with the amplifier via a communication conduit. The amplifier, which may be a modular amplifier or an integral amplifier circuit, is able to amplify and transmit a signal from the programmable digital signal processor to an output device.

To create an audio design in accordance with the invention, a programmable digital signal processor, a power supply connected to the at least one programmable digital signal processor, and an amplifier may be housed in a chassis. A user, via means of a computer which is in communication with the programmable digital signal processor, may select and assign audio elements to create a virtual audio design. The computer and related software may then create a set of instructions from the virtual audio design and the instructions may be transmitted from the computer to the programmable digital signal processor. The digital signal processor may execute the instructions to modify an input signal in order to provide an output signal, and the output signal may then be transmitted by the amplifier to an output device.

As applied to a DSP, “Drag and Drop” is a software methodology allowing a user, by means of a computer, to select (drag) and assign (drop) an audio functional element into a design screen where virtual sound system designs may be created. For example, an audio functional element may be an algorithm to perform an audio function such as compression, limiting, mixing, routing, volume control, or other types of audio processes. Each of the required types of audio processing elements (including, but not limited to, input modules, output modules, mixers, compressors, limiters, expanders, equalizers, routers, signal delays, signal meters, logic routing devices, audio switches, filters, and any other audio processing modules) may, via the use of a computer and associated software, be “dragged” and “dropped” into the design screen in such a way as to allow them to be virtually connected by the software to establish a desired signal flow, thereby forming an audio layout. This audio layout is then translated by the software to create a set of instructions that may be loaded to the digital signal processor. When the DSP executes the instructions, the audio design created on the computer will be replicated in the DSP so that an audio signal will be processed in the desired manner.

An input conduit may be provided to the DSP for receiving an input signal. The input conduit may receive audio signals by means of a suitable communication protocol (RS-232, RS-485, Universal Serial Bus, Ethernet, Infrared, RF (radio frequency, including WiFi (wireless fidelity)), fiber optic, or other suitable means, depending on the need of the user. The user may then transmit a sound system design, in the form of a data file, from a computer to the DSP in order to program the DSP and thereby create specific and unique audio designs at will, by using the Drag and Drop design software. Once the DSP is programmed, the design computer may be disconnected from the DSPA, allowing the DSPA to then perform as a “stand alone” audio processing system.

The user may elicit changes to individual control settings of a design stored in the DSP via the same input conduit while the system is in use. Via use of the design computer or devices included in the chassis and connected to the DSP, and the related software, the user may make changes to audio functions, such as volume, source channel, output channel, etc., to create revisions to the set of instructions previously loaded to the DSP.

The DSPA device may be completely reconfigured for a different audio purpose without the need to change the hardware. A design computer may be connected to the DSPA device by any suitable communications conduit, such as USB, Ethernet, RF, etc. The reconfiguration may they be performed either on site at the location of the DSPA device, or remotely. The DSPA design may create an audio amplifier and processor system that can be altered in the field by a computer, to create an entirely different signal flow and character within the DSPA, all in a single operating chassis.

The DSPA device may include modular power amplifiers, which allow a user to install or remove amplifiers using plug-in amplifier modules. Alternatively, integral power amplifiers (from 1 to 8 power amplifier circuits, all mounted on 1 or 2 circuit boards) may be provided in the chassis. Such amplifier circuits may each be from 10 to 240 watts of RMS (Root Mean Square average power) and may be operated in any quantity that the DSPA chassis will allow—from zero (i.e., all amplifier slots unused, with only a line level output from the DSP boards, to 8—all 8 potential slots occupied with an amplifier module). Specific examples of DSPA devices having differing numbers of modular power amplifiers or integral power amplifiers are given below.

### BRIEF DESCRIPTION OF THE DRAWINGS

The invention is illustrated in the drawings in which like reference characters designate the same or similar parts throughout the figures of which:

FIG. 1 shows a first embodiment of the present invention;

FIG. 2 shows a second embodiment of the present invention;

FIG. 3 shows a third embodiment of the present invention;

FIG. 4 shows a fourth embodiment of the present invention;

FIG. 5 shows a faceplate for use in connection with the first and second embodiments of the present invention; and

FIG. 6 shows a faceplate for use in connection with the third and fourth embodiments of the present invention.

### DETAILED DESCRIPTION OF THE INVENTION

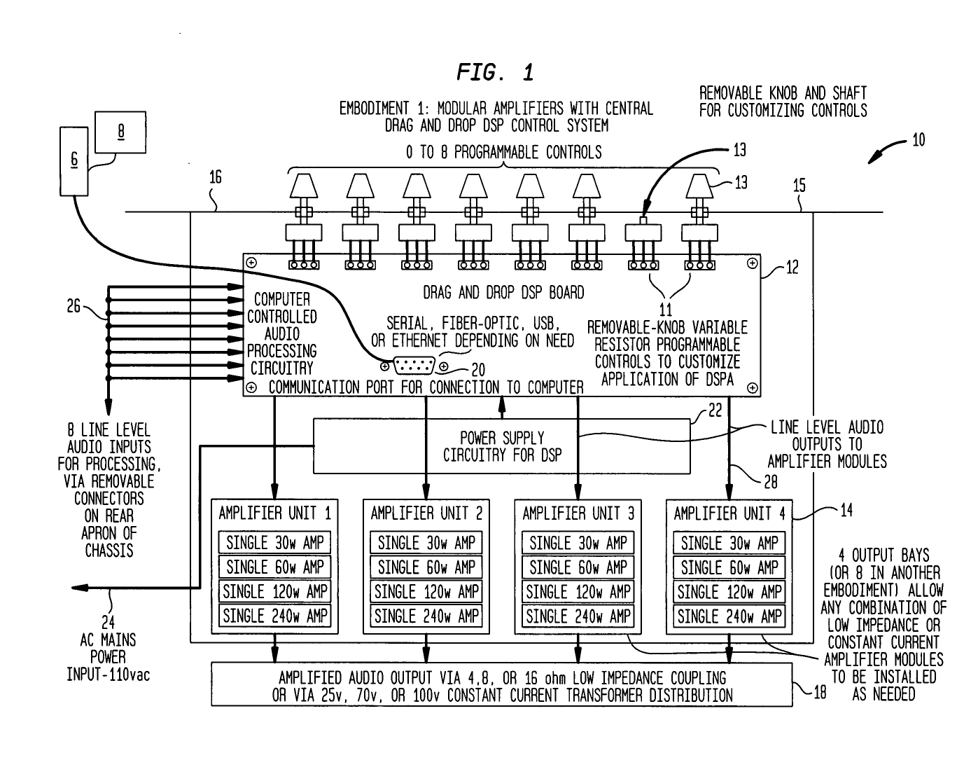

A DSPA device according to the invention may have a DSP circuit board and a power amplifier system integrally housed within a chassis. The amplifier system may have a number of discrete removable amplifier modules, as determined by the need of the user. Alternatively, the amplifier system may include a number of amplifier channels mounted on one or more circuit boards. In one embodiment, between one and eight amplifier modules, or between one and eight amplifier channels mounted on a monolithic circuit board, may be utilized. In another embodiment, the DSPA may have one DSP circuit board and four amplifier modules or four amplifier channels mounted on a monolithic circuit board. Specific examples of DSPA devices having differing numbers of modular power amplifiers or integral power amplifiers are identified in FIGS. 1-4.

A first embodiment of the invention is shown in FIG. 1. The DSPA device 10 shown in FIG. 1 has a single programmable DSP circuit board 12 and four removable (“modular”) amplifiers 14 housed within a chassis 16. The chassis 16 may be, for example, a standard 19″ by 2″ rack unit which may be mounted in a rack system with other components. A power supply circuit 22, which may power the DSP 12, may be connected to a standard external power supply 24, such as a standard 110 volt AC power outlet. In order to program the DSP, a communications port 20 may be provided and used to allow a computer 6 to be selectively connected to the DSP circuit board 12 via a communication port 20. The computer 6 and DSP 12 may communicate via the port 20 using a suitable communication protocol, such as RS-232, RS-485, Universal Serial Bus (USB), Ethernet, Infrared, RF (radio frequency, including WiFi (wireless fidelity)), fiber optic, or other suitable means, depending upon the need of the user. Eight line level audio inputs 26 may be removably connected to the DSP circuit board 12. Via the use of the computer and associated software, each of the line level audio inputs 26 may be virtually “dragged” and “dropped” into the design screen 8 in such a way as to allow them to be connected within the software to establish a desired signal flow, forming a desired audio layout.

The DSP circuit board 12 may also have variable resistor programmable controls 11 which may be programmed via the drag and drop software for appropriate function as desired (e.g., volume, tone, parameters, etc.) Removable knobs and shafts 13 may be connected to the DSP circuit board 12, installed through the faceplate 15 on the front of the chassis 16. The knobs and shafts 13 may be selectively added or removed from the faceplate 15 of the DSPA device 10 so that only the desired (i.e., programmed via the software) variable resistor controls are available for operation by a user. In this matter, a manufacturer may easily customize a DSPA for a customer at the manufacturer's place of business, rather than at the end user's place of business.

After the user has dragged and dropped the desired audio functional elements into the design screen, a desired signal flow is established which forms an audio layout. This audio layout may then be used to create a set of instructions, which programs the DSP to conform to the desired audio layout. Once programmed, the DSP may receive an input signal, process that signal, and provide an output signal, which may be sent to the amplifiers 14 via a communication conduit 28. The amplifiers 14 may then transmit the signal to an external output device 18, such as loudspeakers.

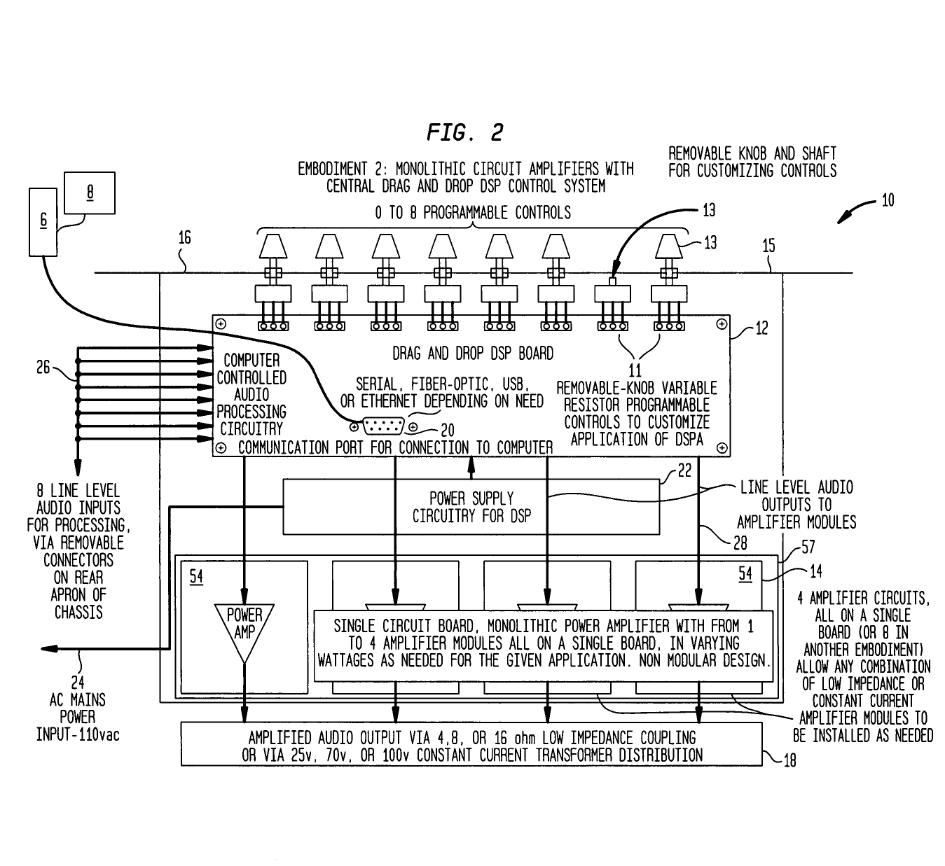

A second embodiment of the invention is shown in FIG. 2. This embodiment is similar to the first embodiment, except that four integral amplifier circuits 54 are shown mounted on a single monolithic circuit board 57. The amplifier circuits 54 may be of any range of power wattage outputs, depending upon the need of the user.

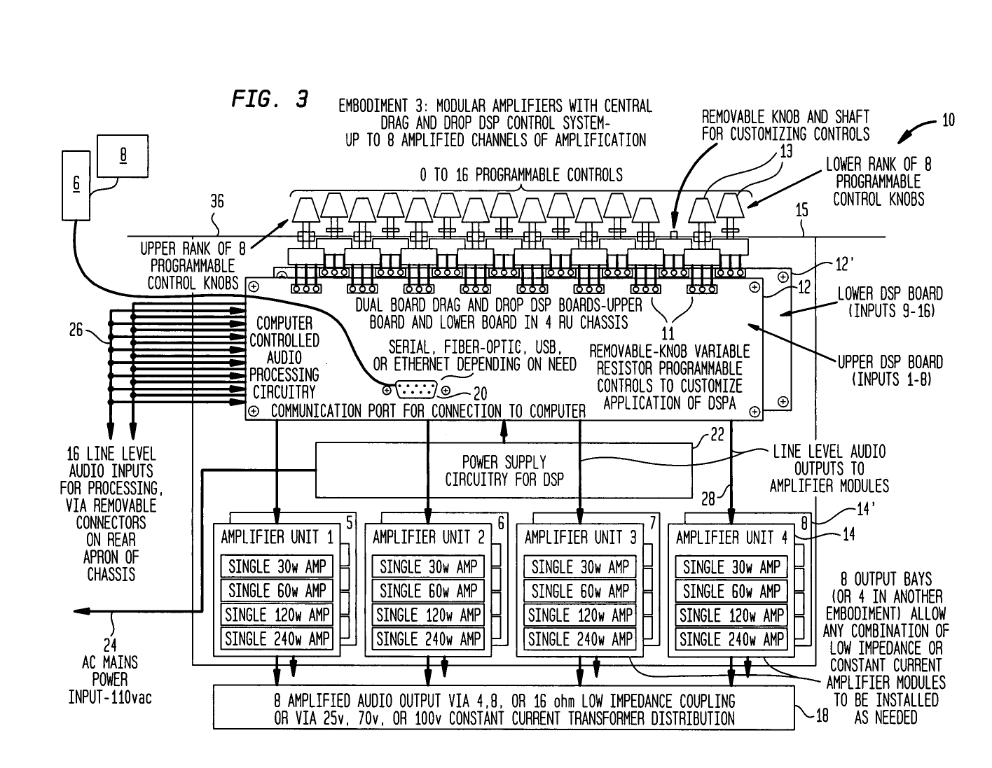

A third embodiment of the invention is shown in FIG. 3. This embodiment is similar to the first embodiment, except that a second programmable DSP circuit board 12′ is included in the DSPA. Each DSP 12, 12′ may drive four modular amplifiers 14 and 14′, respectively, for a total of eight removable amplifier modules. The dual programmable DSP circuit boards 12 and 12′ and the eight modular amplifiers 14 and 14′ may be housed together within a chassis 36. The chassis 36 may be, for example, a standard 19″ by 4″ rack unit.

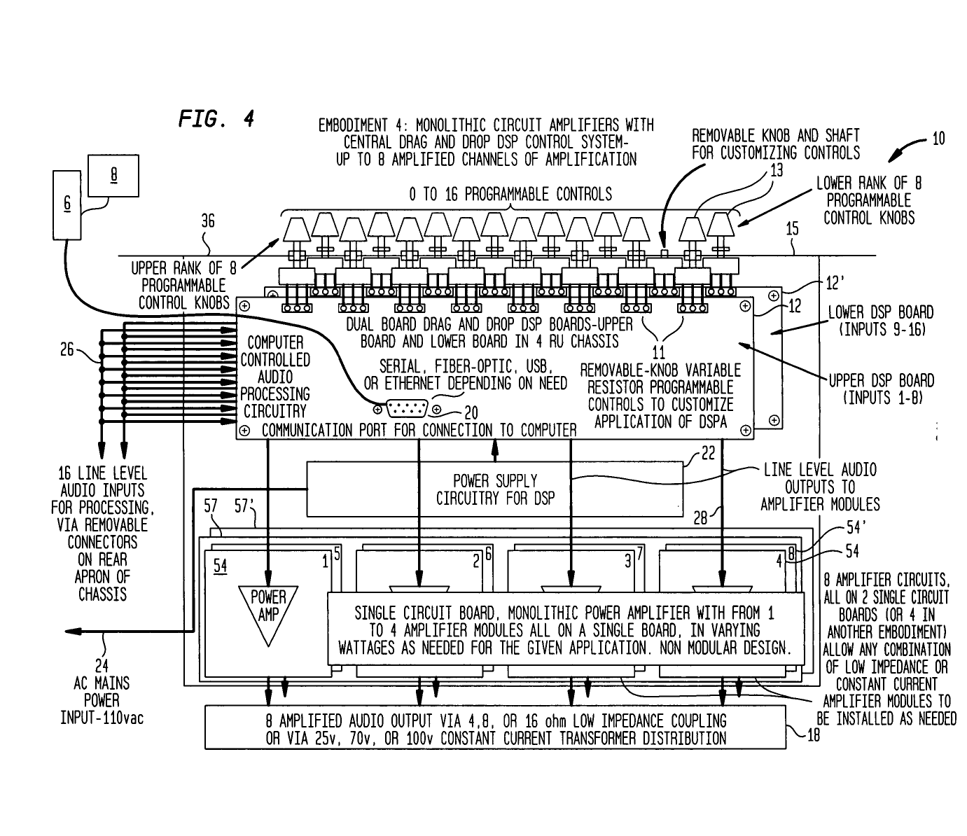

A fourth embodiment of the invention is shown in FIG. 4. This embodiment is similar to the second and third embodiment except that dual programmable DSP circuit boards 12 and 12′ each may drive four integral amplifier circuits 54 and 54′, which are each mounted on a monolithic circuit board 57 and 57′, for a total of eight integral amplifier circuits 54 and 54′. The dual programmable DSP circuit boards 12 and 12′ and the two integral amplifier circuit boards 57 and 57′ may be all housed within a chassis 36.

The first and third embodiments of the invention may be designed to allow for a flexible format, whereby an installer or user may increase or decrease the power output of a given channel by simply removing a power amplifier module and replacing it with another. In the event that no audio power amplification is needed, the installer or user may remove all power amplifier modules so that the DSP circuit board, with line level outputs only, is the sole operating portion of the DSPA device.

The third and fourth embodiments may include dual programmable digital signal processors. Devices constructed as described in the third and fourth embodiments may facilitate mass production of DSPA devices with highly unique arrangements of amplifier channel output levels suited to a particular user's needs, and housed in a single chassis.

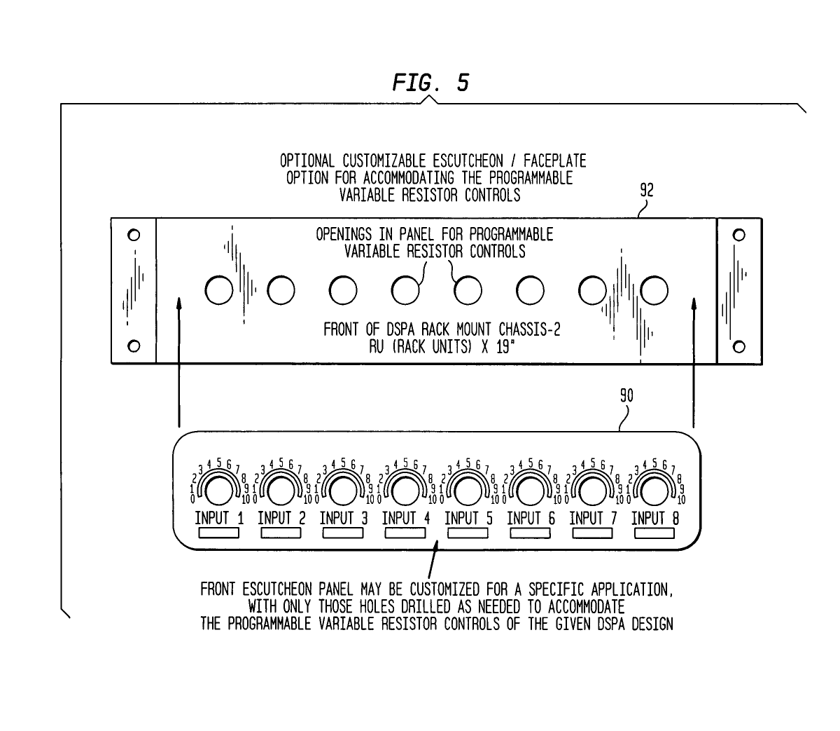

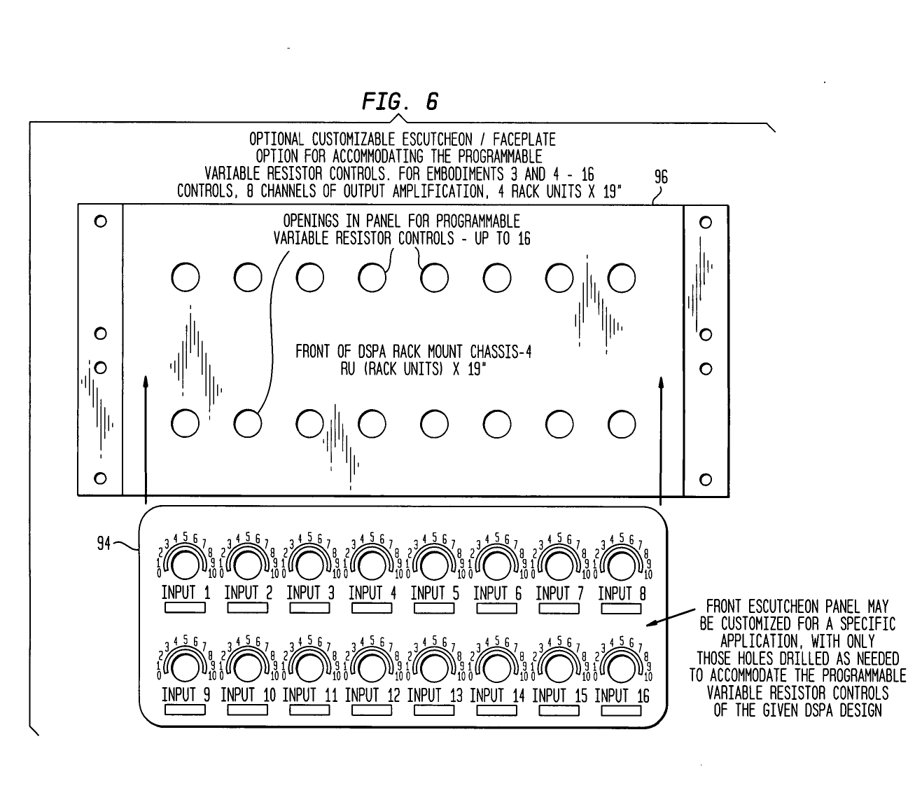

As shown in FIG. 5, a faceplate 92 and custom escutcheon 90 may be used with the first and second embodiments described above. The escutcheon 90 may be applied to the face of the DSPA device to cover unused holes and provide labeling for the variable resistor controls that are utilized. As shown in FIG. 6, a faceplate 96 and custom escutcheon 94 may be used with the third and fourth embodiments described above to cover unused holes and provide labeling for the variable resistor controls that are utilized.

While the invention has been described in connection with certain embodiments, it should be understood that it is not intended that the invention be limited to the particular details illustrated in the accompanying drawings and as described above. On the contrary, it is to be understood that the embodiments of the invention, while preferred, can be readily changed or altered by one skilled in the art and that these embodiments are not to be limiting or constraining on the form or benefits of the invention.

What is claimed is:

1. A digital signal processing amplifier device comprising:
a chassis;
at least one programmable digital signal processor housed in the chassis;
a power supply housed within the chassis and connected to the at least one programmable digital signal processor;
at least one amplifier housed in the chassis;
wherein the at least one programmable digital signal processor is in communication with the at least one amplifier via a communication conduit; and
wherein the at least one amplifier is able to amplify and transmit a signal from the programmable digital signal processor to an output device.

2. The device of claim 1 wherein the amplifier may be a modular amplifier.

3. The device of claim 1 wherein the amplifier may be an amplifier circuit integrated on a circuit board.

4. The device of claim 1 wherein the output device is located outside the chassis.

5. The device of claim 1 wherein the output device is a speaker.

6. A method of creating an audio design comprising the steps of:
providing a chassis;
providing at least one programmable digital signal processor housed in the chassis;
providing a power supply housed in the chassis and connected to the at least one programmable digital signal processor;
providing at least one amplifier housed in the chassis;
providing a computer in communication with the programmable digital signal processor;
selecting and assigning audio elements via the computer to create a virtual audio design;
creating a set of instructions from the virtual audio design;
transmitting the instructions from the computer to the programmable digital signal processor;
executing the instructions in the programmable digital signal processor to modify an input signal in order to provide an output signal; and
transmitting the output signal to the at least one amplifier via a communication conduit;
wherein the at least one amplifier amplifies and transmits the digital signal to an output device.

7. The method of claim 6 wherein the amplifier may be a modular amplifier.

8. The method of claim 6 wherein the amplifier may be an amplifier circuit integrated on a circuit board.

9. The method of claim 6 wherein the output device is located outside the chassis.

10. The method of claim 6 wherein the output device is a speaker.
